(19) United States
(12) Patent Application Publication
(10) Pub. No.: US 2016/0113160 A1
(43) Pub. Date: Apr. 21, 2016

(54) ELECTROMAGNETIC SHIELDING STRUCTURE OF ELECTRONIC PART

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventor: GUANG-FENG OU, Wuhan (CN)

(21) Appl. No.: 14/522,382

(22) Filed: Oct. 23, 2014

(30) Foreign Application Priority Data
Oct. 17, 2014 (CN) 201410550930.4

(51) Int. Cl. H05K 9/00; H05K 7/14

(52) U.S. Cl. CPC H05K 9/0007; H05K 7/1427

(57) ABSTRACT

An electromagnetic shielding structure includes a bottom plate, a plurality of securing stands, and a circuit board. The circuit board is located among the plurality of securing stands and a shielding layer is laid on a top surface of the circuit board. The bottom plate, the plurality of securing stands, and the circuit board cooperatively define a closed space configured to receive an electronic part attached to a bottom surface of the circuit board, and the bottom plate, the plurality of securing stands and the circuit board are configured to shield electromagnetic of the electronic part.

### CROSS-REFERENCE TO RELATED APPLICATIONS

This application claims priority to Chinese Patent Application No. 201410550930.4 filed on Oct. 17, 2014, the contents of which are incorporated by reference herein.

### FIELD

The subject matter herein generally relates to electromagnetic shielding structure.

### BACKGROUND

Electronic devices, such as computers, include a plurality of electronic parts which may create electromagnetic.

### BRIEF DESCRIPTION OF THE DRAWINGS

Implementations of the present technology will now be described, by way of example only, with reference to the attached figures.

FIG. 1 is an exploded, isometric view of an electronic device.

FIG. 2 is an assembled view of the electronic device of FIG. 1.

FIG. 3 is a cross sectional view of taken along a line III-III of FIG. 2.

FIG. 4 is an enlarged view of circle IV of FIG. 3.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

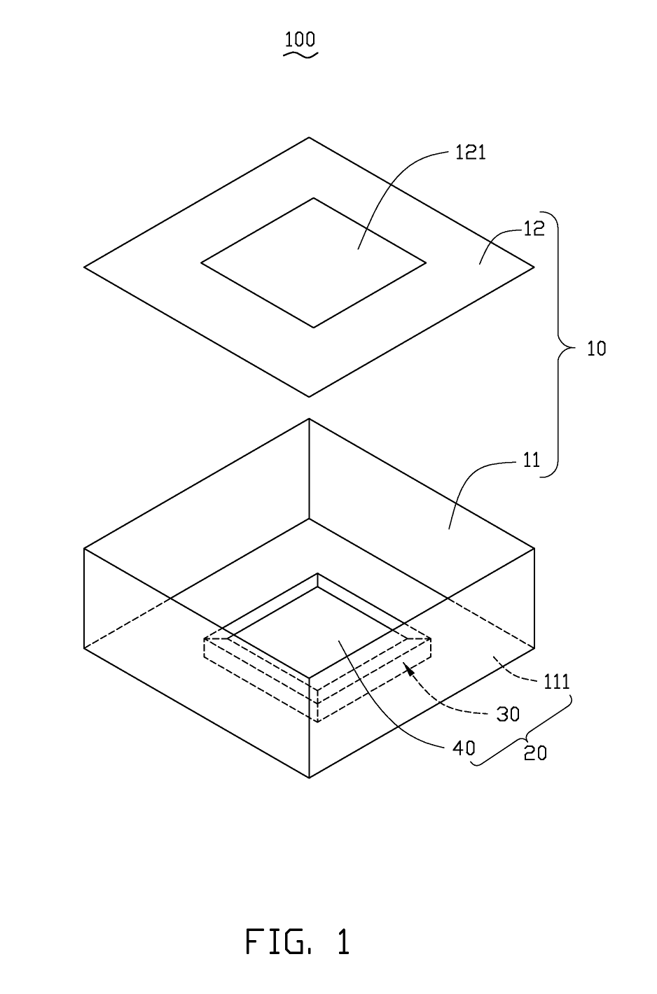

FIG. 1 illustrates an electronic device in accordance with one embodiment. The electronic device can include an enclosure 10, an installation member 30, and a circuit board 40. The installation member 30 can be detachably secured to the enclosure 10, and the circuit board 40 can be secured to the installation member 30.

The enclosure 10 can include a base 11 and a cover plate 12 for covering the base 11. The base 11 can include a bottom plate 111 substantially parallel with the cover plate 12. In at least one embodiment, the bottom plate 111 can be made of metal material, such as copper, aluminium, iron, and so on. A monitor 121 can be installed on the cover plate 12. The bottom plate 111, the circuit board 40, and the installation member 30 can form an electromagnetic shielding structure 20.

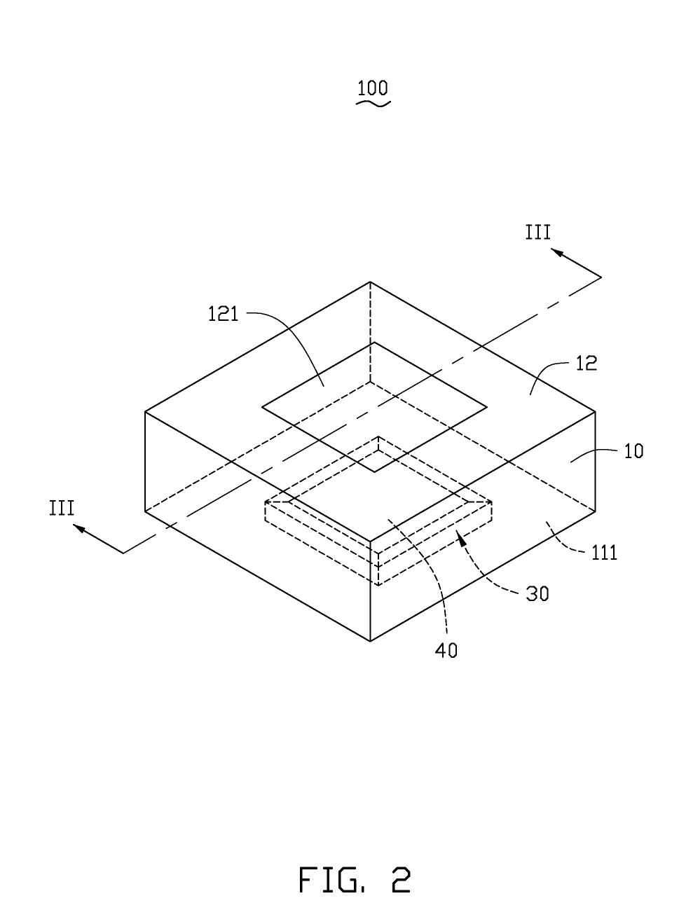

FIGS. 2-4 illustrate that the installation member 30 can include a plurality of securing stands 35 corresponding to the circuit board 40 and surrounding the circuit board 40. In at least one embodiment, the circuit board 40 is substantially rectangular, and there are four securing stands 35. Each securing stand 35 can include a top piece 31, a bottom piece 32, a connecting piece 33, and a dividing piece 34. The connecting piece 33 can be coupled to the top piece 31 and the second connecting piece 32. The dividing piece 34 can extend from the connecting piece 33. In at least one embodiment, the top piece 31 and the bottom piece 32 are parallel to each other and perpendicular to the connecting piece 33, the dividing piece 34 is substantially parallel with the top piece 31 and the bottom piece 32, the dividing piece 34 is substantially perpendicular to the connecting piece 33, each stand 35 has an E-shaped cross-section.

The circuit board 40 can include a bottom surface 41 and a top surface 42 opposite to the bottom surface 41. An electronic part 411 can be attached to the bottom surface 41. A shielding layer 421 can be laid in the top surface 42. In at least one embodiment, the shielding layer 421 is made of copper foil.

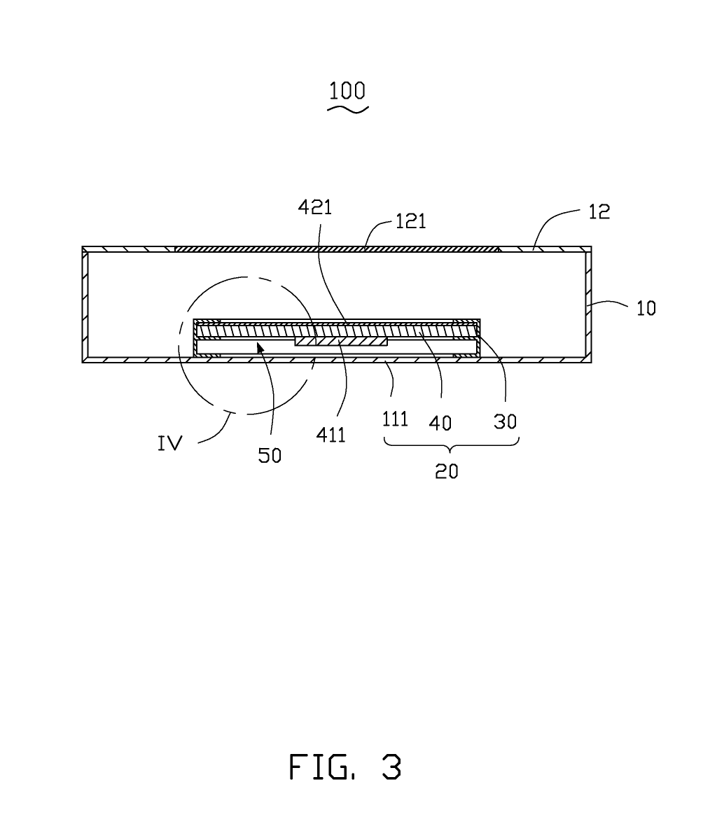

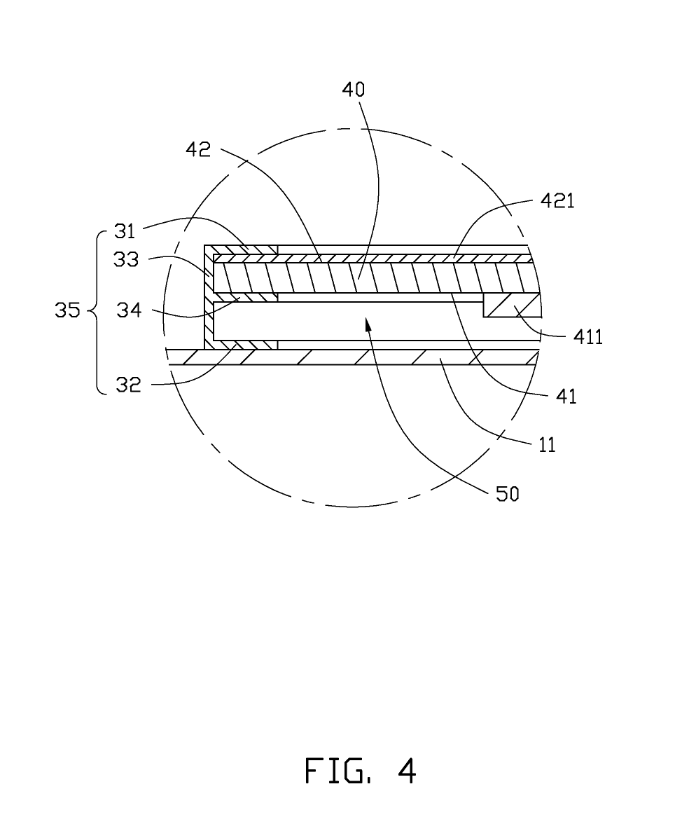

Referring to FIGS. 3 and 4, in assembly, the circuit board 40 can be located between the top piece 31 and dividing piece 34, so that the circuit board 40 is secured to the plurality of securing stands 35. The shielding layer 421 abuts the top pieces 31. The electronic part 411 can face to the bottom plate 111. Each stand 35 can be secured to the bottom plate via well know ways, such as bolting, screwing, welding, sticking and so on. Therefore a closed space 50 is defined among the plurality of securing stands 35, the bottom plate 111 and the circuit board 40. The electronic part 411 can be received in the closed space 50, and the plurality of securing stands 35, the bottom plate 111 and the circuit board 40 can shield electromagnetic of the electronic part 411. A distance between the dividing piece 34 and the bottom piece 32 is greater than a distance between the electronic part 411 and the bottom piece 32.

The embodiments shown and described above are only examples. Many details are often found in the art such as the other features of an electromagnetic shielding structure. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. An electromagnetic shielding structure comprising:
a bottom plate;
a plurality of securing stands;
a circuit board located among the plurality of securing stands; and
a shielding layer on a top surface of the circuit board;
wherein the bottom plate, the plurality of securing stands, and the circuit board cooperatively define a closed space configured to receive an electronic part attached to a bottom surface of the circuit board, and
the bottom plate, the plurality of securing stands and the circuit board are configured to shield electromagnetic of the electronic device.

2. The electromagnetic shielding structure of claim 1, wherein each securing stand comprises a top piece and a dividing piece, and the circuit board is located between the top piece and the dividing piece.

3. The electromagnetic shielding structure of claim 2, wherein each securing stand further comprises a bottom piece, the bottom piece is secured to the bottom plate, the top piece abuts the resists the shielding layer, and the dividing piece resists the bottom surface.

4. The electromagnetic shielding structure of claim 3, wherein a distance between the dividing piece and the bottom piece is greater than a distance between the electronic part and the bottom piece.

5. The electromagnetic shielding structure of claim 3, wherein each securing stand further comprises a connecting piece, and the connecting piece is coupled to the top piece, the dividing piece and the bottom piece.

6. The electromagnetic shielding structure of claim 5, wherein the top piece, the bottom piece and the dividing piece are substantially parallel to the bottom plate and substantially perpendicular to the connecting piece.

7. The electromagnetic shielding structure of claim 1, wherein each securing stand is substantially E-shaped.

8. An electronic device comprising:
a base comprising a bottom plate;
an installation member detachably secured to the bottom plate; and
a circuit board engaged with the installation member;
wherein the bottom plate, the installation member, and the circuit board cooperatively define a closed space configured to receive an electronic part attached to a bottom surface of the circuit board, and the bottom plate, the plurality of securing stands and the circuit board are configured to shield electromagnetic of the electronic part.

9. The electronic device of claim 8, wherein the installation member comprises a plurality of securing stand, and the circuit board is located among the plurality of securing stands and a shielding layer is laid on a top surface of the circuit board and is configured to shield electromagnetic.

10. The electronic device of claim 9, wherein each securing stand comprises a top piece and a dividing piece, and the circuit board is located between the top piece and the dividing piece.

11. The electronic device of claim 10, wherein each stand further comprises a bottom piece, the bottom piece is secured to the bottom plate, the top piece abuts the resists the shielding layer, and the dividing piece resists the bottom surface.

12. The electronic device of claim 11, wherein a distance between the dividing piece and the bottom piece is greater than a distance between the electronic part and the bottom piece.

13. The electronic device of claim 11, wherein each securing stand further comprises a connecting piece, and the connecting piece is coupled to the top piece, the dividing piece and the bottom piece.

14. The electronic device of claim 13, wherein the top piece, the bottom piece and the dividing piece are substantially parallel to the bottom plate and substantially perpendicular to the connecting piece.

15. The electronic device of claim 9, wherein each securing stand is substantially E-shaped.

16. An electronic device comprising:
a base comprising a bottom plate;
a plurality of securing stands detachably secured to the bottom plate; and
a circuit board located among the plurality of securing stands and a shielding layer being laid on a top surface of the circuit board;
wherein the bottom plate, the plurality of securing stands, and the circuit board cooperatively define a closed space configured to receive an electronic part attached to a bottom surface of the circuit board, and the bottom plate, the plurality of securing stands and the circuit board are configured to shield electromagnetic of the electronic part.

17. The electronic device of claim 16, wherein each securing stand comprises a top piece and a dividing piece, and the circuit board is located between the top piece and the dividing piece.

18. The electronic device of claim 17, wherein each securing stand further comprises a bottom piece, the bottom piece is secured to the bottom plate, the top piece abuts the resists the shielding layer, and the dividing piece resists the bottom surface.

19. The electronic device of claim 18, wherein a distance between the dividing piece and the bottom piece is greater than a distance between the electronic part and the bottom piece.

20. The electronic device of claim 18, wherein each securing stand further comprises a connecting piece, and the connecting piece is coupled to the top piece, the dividing piece and the bottom piece.
